(19) United States
(12) Patent Application Publication
(10) Pub. No.: US 2011/0057268 A1
(43) Pub. Date: Mar. 10, 2011

(54) SEMICONDUCTOR DEVICE AND METHOD FOR FABCRICATING THE SAME

(76) Inventor: Tsuyoshi MAKITA, Toyama (JP)

(21) Appl. No.: 12/853,848

(22) Filed: Aug. 10, 2010

(30) Foreign Application Priority Data
Sep. 4, 2009 (JP) 2009-205020

(51) Int. Cl. H01L 27/06; H01L 21/8234

(52) U.S. Cl. 257/380; 438/384; 438/238; 257/E21.616; 257/E27.016

(57) ABSTRACT

A semiconductor device includes a resistive element and a MISFET. The resistive element includes a first conductive film formed on the semiconductor substrate and containing a metal, a second conductive film formed on the first conductive film and containing silicon, and an insulating film formed between the first conductive film and the second conductive film.

### CROSS-REFERENCE TO RELATED APPLICATION

This application claims priority to Japanese Patent Application No. 2009-205020 filed on Sep. 4, 2009, the disclosure of which including the specification, the drawings, and the claims is hereby incorporated by reference in its entirety.

### BACKGROUND

The present disclosure relates to semiconductor devices each including a resistive element and a metal insulator semiconductor field effect transistor (MISFET), and methods for fabricating the same, and more particularly relates to a semiconductor device which includes a resistive element and a MISFET including a gate electrode containing metal, and a method for fabricating the same.

In recent years, techniques for increasing the scale of integration of integrated circuits and techniques allowing higher-speed signal processing thereof have been significantly developed, and thus, miniaturization of transistors has been accelerated.

High-speed signal processing of an integrated circuit requires that the impedance matching between input and output sides of the circuit be obtained using a resistance circuit. To meet this requirement, a resistive element having a resistance corresponding to the characteristic impedance of a transmission line is generally incorporated into an integrated circuit. Silicon is generally used as a material of such a resistive element.

A method for forming a resistive element using polycrystalline silicon as a material of the resistive element will be described hereinafter with reference to FIG. 9 (see, e.g., Japanese Patent Publication No. 2001-308270). FIG. 9 is a cross-sectional view illustrating the structure of a conventional semiconductor device.

A polycrystalline silicon film 101 is formed on a semiconductor substrate 100, and then, boron ions are implanted into the polycrystalline silicon film 101. Thereafter, the resultant polycrystalline silicon film 101 is annealed. In this way, a resistive element is formed.

A polycrystalline silicon film 101 of a semiconductor device including a resistive element and a bipolar transistor can be formed simultaneously with a base lead (not illustrated) of an npn transistor.

### SUMMARY

However, semiconductor devices each including a resistive element and a MISFET have presented the following problems.

In recent years, the use of a high-dielectric-constant material, such as hafnia (HfO₂), lanthanum oxide (La₂O₃), or zirconia (ZrO₂), as a material of a gate insulating film has been promoted.

Furthermore, the use of a refractory metal, such as titanium (Ti), tantalum (Ta), or molybdenum (Mo), as a material of a gate electrode has been promoted, and gate electrodes have been developed which each have a metal-inserted poly-silicon stack (MIPS) structure including a refractory metal film interposed between a gate insulating film and a polysilicon film. However, semiconductor devices each including a MISFET with a gate electrode having a MIPS structure have presented the following problem. The resistivities of a refractory metal and a compound of the refractory metal are typically lower than the resistivity of polysilicon. Therefore, when a resistive element includes a refractory metal film and a polysilicon film (i.e., when an interconnect is formed simultaneously with a gate electrode of a MISFET, and the interconnect is used as the resistive element), the resistive element cannot provide a sufficient resistance (a resistance required to function as a resistive element).

First, for example, when the lengths of interconnects used as resistive elements are increased in order to allow such resistive elements to each provide a sufficient resistance, miniaturization of MISFETs is difficult. Second, for example, when the widths of such interconnects are reduced in order to allow such resistive elements to each provide a sufficient resistance, this causes the interconnects to have different widths. This causes the resistive elements to operate at different performance levels.

Otherwise, examples of possible processes for allowing a resistive element to provide a sufficient resistance include the following process. Specifically, a refractory metal film is formed on a resistive element region where a resistive element is to be formed and a MISFET region where a MISFET is to be formed. Thereafter, a portion of the refractory metal film corresponding to the resistive element region is removed by etching using a mask covering the MISFET region, and then the mask is removed. Thereafter, a polysilicon film is formed to cover the resistive element region and the MISFET region, and a resistive element including only a portion of the polysilicon film is formed on the resistive element region, and a gate electrode including a remaining portion of the refractory metal film and another portion of the polysilicon film is formed on the MISFET region. However, this configuration causes the following problems. Even with the removal of the mask, the entire mask cannot be removed, and thus, part of the mask remains on a portion of the refractory metal film corresponding to the MISFET region. In other words, mask residue remains. Therefore, the mask residue is interposed between the refractory metal film and the polysilicon film. Such residue may cause poor patterning of gate electrodes. Such residue may increase the interface resistance between the refractory metal film and the polysilicon film; and/or may cause variations in the interface resistance, leading to deterioration of the characteristics of a corresponding MISFET.

In view of the above, an object of the present disclosure is to provide a semiconductor device including a resistive element and a MISFET with a gate electrode containing metal and configured such that the resistive element provides a sufficient resistance without causing poor patterning of gate electrodes and deterioration of the characteristics of the MISFET.

In order to achieve the above-described object, a semiconductor device according to a first aspect of the present disclosure is directed to a semiconductor device including: a resistive element; and a MISFET. The resistive element includes: a first conductive film formed on a semiconductor substrate and containing a metal; a second conductive film formed on the first conductive film and containing silicon; and an insulating film formed between the first conductive film and the second conductive film.

According to the semiconductor device of the first aspect of the present disclosure, the resistive element includes the insulating film providing electrical isolation between the first conductive film containing the metal and the second conductive film containing silicon. Thus, the resistive element can provide a sufficient resistance. Therefore, a semiconductor device can be provided which includes an integrated circuit enabling high-speed signal processing.

In order to achieve the above-described object, a semiconductor device according to a second aspect of the present disclosure is directed to a semiconductor device including: a resistive element; and a MISFET. The resistive element includes: a first conductive film formed on a semiconductor substrate and containing a metal; a second conductive film formed on the first conductive film and containing silicon; and an insulating film formed between lower and upper parts of the second conductive film.

According to the semiconductor device of the second aspect of the present disclosure, the resistive element includes the insulating film providing electrical isolation between the lower and upper parts of the second conductive film containing silicon. Thus, the resistive element can provide a sufficient resistance. Therefore, a semiconductor device can be provided which includes an integrated circuit enabling high-speed signal processing.

In the semiconductor device according to the first or second aspect of the present disclosure, the MISFET preferably includes: a gate insulating film formed on the semiconductor substrate; and a gate electrode including a third conductive film formed on the gate insulating film, and a fourth conductive film formed on the third conductive film.

Since no etching residue is, thus, interposed between the third conductive film and the fourth conductive film, this prevents poor patterning of the gate electrode. In addition, since no etching residue is interposed between the third conductive film and the fourth conductive film, this prevents the interface resistance between the third conductive film and the fourth conductive film from increasing, and prevents variations in the interface resistance. Such prevention can avoid deterioration of the characteristics of the MISFET.

In view of the above, the resistive element which can provide a sufficient resistance can be achieved without causing poor patterning of the gate electrode and deterioration of the characteristics of the MISFET.

In the semiconductor device according to the first or second aspect of the present disclosure, a material of the first conductive film is preferably identical with a material of the third conductive film, and a material of the second conductive film is preferably identical with a material of the fourth conductive film.

In the semiconductor device according to the first aspect of the present disclosure, the insulating film is preferably an oxide film containing Hf, Zr, La, Al, Lu, Gd, or Si, a nitride film containing Hf, Zr, La, Al, Lu, Gd, or Si, or an oxynitride film containing Hf, Zr, La, Al, Lu, Gd, or Si.

In the semiconductor device according to the first or second aspect of the present disclosure, the insulating film is preferably an oxide film containing the silicon, a nitride film containing the silicon, or an oxynitride film containing the silicon.

In the semiconductor device according to the first or second aspect of the present disclosure, the insulating film is preferably an oxide film containing the metal, a nitride film containing the metal, or an oxynitride film containing the metal.

In the semiconductor device according to the first or second aspect of the present disclosure, the first conductive film is preferably a nitride film containing the metal, a carbide film containing the metal, or a silicon compound film containing the metal.

In the semiconductor device according to the first or second aspect of the present disclosure, the metal is preferably at least one of Al, Fe, Cu, Ni, Co, Ti, Ta, Nb, W, Mo, V, Pt, and Au.

In the semiconductor device according to the first or second aspect of the present disclosure, the second conductive film is preferably a polysilicon film, an amorphous silicon film, or a monocrystalline silicon film.

In order to achieve the above-described object, a method for fabricating a semiconductor device according to a third aspect of the present disclosure is directed to a method for fabricating a semiconductor device including a resistive element formed on a resistive element region, and a MISFET formed on a MISFET region. The method includes: forming a first conductive film formation film containing a metal on a semiconductor substrate; forming an insulating film formation film on the first conductive film formation film; removing a portion of the insulating film formation film corresponding to the MISFET region; after the removing, forming a second conductive film formation film which contains silicon and covers a remaining portion of the insulating film formation film and a portion of the first conductive film formation film corresponding to the MISFET region; and after the forming the second conductive film formation film, sequentially patterning portions of the second conductive film formation film, the insulating film formation film, and the first conductive film formation film corresponding to the resistive element region, thereby forming the resistive element on the semiconductor substrate, where the resistive element includes a first conductive film made of the first conductive film formation film, an insulating film made of the insulating film formation film, and a second conductive film made of the second conductive film formation film.

According to the method of the third aspect of the present disclosure, the resistive element can be formed which includes the insulating film providing electrical isolation between the first conductive film containing metal and the second conductive film containing silicon. Therefore, the resistive element can be achieved which can provide a sufficient resistance.

Instead of a photoresist film, an anti-reflective film, or other films, the insulating film formation film made of, e.g., silicon dioxide (SiO₂) is formed on the first conductive film formation film. Since no residue of the insulating film formation film, therefore, remains on the first conductive film formation film after removal of the insulating film formation film, no residue of the insulating film formation film is interposed between portions of the first and second conductive film formation films corresponding to the MISFET region.

The method of the third aspect of the present disclosure preferably further includes: before the forming the first conductive film formation film, forming a gate insulating film formation film on a portion of the semiconductor substrate corresponding to the MISFET region; and after the forming the second conductive film formation film, sequentially patterning portions of the second conductive film formation film, the first conductive film formation film, and the gate insulating film formation film corresponding to the MISFET region, thereby sequentially forming a gate insulating film made of the gate insulating film formation film, and a gate electrode on the semiconductor substrate, where the gate electrode includes a third conductive film made of the first conductive film formation film and a fourth conductive film made of the second conductive film formation film. The sequentially patterning the portions corresponding to the resistive element region and the sequentially patterning the portions corresponding to the MISFET region are preferably simultaneously performed.

As described above, since no residue of the insulating film formation film is, thus, interposed between the first conductive film formation film and the second conductive film formation film, this prevents poor patterning of the gate electrode. In addition, since no residue of the insulating film formation film is interposed between the third conductive film and the fourth conductive film, this prevents the interface resistance between the third conductive film and the fourth conductive film from increasing, and prevents variations in the interface resistance. Such prevention can avoid deterioration of the characteristics of the MISFET.

In view of the above, the resistive element which can provide a sufficient resistance can be achieved without causing poor patterning of the gate electrode and deterioration of the characteristics of the MISFET.

In order to achieve the above-described object, a method for fabricating a semiconductor device according to a fourth aspect of the present disclosure is directed to a method for fabricating a semiconductor device including a resistive element formed on a resistive element region, and a MISFET formed on a MISFET region. The method includes: forming a first conductive film formation film containing a metal on a semiconductor substrate; forming a second conductive film formation film containing silicon on the first conductive film formation film; implanting oxygen ions, nitrogen ions, or oxygen and nitrogen ions into an interface region between portions of the first and second conductive film formation films corresponding to the resistive element region, or the portion of the second conductive film formation film corresponding to the resistive element region by ion implantation, thereby forming an ion containing layer formation layer; after the implanting, patterning portions of the second conductive film formation film, the ion containing layer formation layer, and the first conductive film formation film corresponding to the resistive element region, thereby forming a first conductive film, an ion containing layer, and a second conductive film on the semiconductor substrate, where the first conductive film is made of the first conductive film formation film, the ion containing layer is made of the ion containing layer formation layer, and the second conductive film is made of the second conductive film formation film; and reacting oxygen, nitrogen, or oxygen and nitrogen contained in the ion containing layer with the silicon or the metal by heat treatment, thereby forming an insulating film. In the reacting, the resistive element including the first conductive film, the insulating film, and the second conductive film is formed.

According to the method of the fourth aspect of the present disclosure, the resistive element can be formed which includes the insulating film providing electrical isolation between the first conductive film containing the metal and the second conductive film containing silicon, or the insulating film providing electrical isolation between lower and upper parts of the second conductive film containing silicon. Therefore, the resistive element can be achieved which can provide a sufficient resistance.

In addition, the ion containing layer formation layer is formed by implanting ions into the interface region between the first and second conductive film formation films, or the second conductive film formation film, and then the insulating film is formed by utilizing the ion containing layer formation layer. Therefore, the first and second conductive film formation films can be successively formed. This prevents etching residue and mask residue from being interposed between the first and second conductive film formation films.

Furthermore, the thickness of the insulating film (in other words, the thickness of a portion of the second conductive film which will be used as the insulating film) can be controlled by adjusting the ion implantation conditions for the ion containing layer formation layer and adjusting the heat treatment conditions for the insulating film. Since the thickness of the second conductive film of the resistive element can, therefore, be controlled, the resistance of the resistive element can be controlled without changing an interconnect pattern.

The method of the fourth aspect of the present disclosure preferably further includes: before the forming the first conductive film formation film, forming a gate insulating film formation film on a portion of the semiconductor substrate corresponding to the MISFET region; and after the implanting, sequentially patterning portions of the second conductive film formation film, the first conductive film formation film, and the gate insulating film formation film corresponding to the MISFET region, thereby sequentially forming a gate insulating film made of the gate insulating film formation film, and a gate electrode on the semiconductor substrate, where the gate electrode includes a third conductive film made of the first conductive film formation film and a fourth conductive film made of the second conductive film formation film. The patterning the portions corresponding to the resistive element region and the sequentially patterning the portions corresponding to the MISFET region are preferably simultaneously performed.

As described above, since neither of etching residue and mask residue is, thus, interposed between the first and second conductive film formation films, this prevents poor patterning of the gate electrode. In addition, since neither of etching residue and mask residue is interposed between the third and fourth conductive films, this prevents the interface resistance between the third and fourth conductive films from increasing, and prevents variations in the interface resistance. Such prevention can avoid deterioration of the characteristics of the MISFET.

In view of the above, the resistive element which can provide a sufficient resistance can be achieved without causing poor patterning of the gate electrode and deterioration of the characteristics of the MISFET.

In order to achieve the above-described object, a method for fabricating a semiconductor device according to a fifth aspect of the present disclosure is directed to a method for fabricating a semiconductor device including a resistive element formed on a resistive element region and a MISFET formed on a MISFET region. The method includes acts of: forming a first conductive film formation film containing a metal on a semiconductor substrate; forming a second conductive film formation film containing silicon on the first conductive film formation film; after the forming the second conductive film formation film, sequentially patterning portions of the second conductive film formation film and the first conductive film formation film corresponding to the resistive element region, thereby sequentially forming a first conductive film and a second conductive film on the semiconductor substrate, where the first conductive film is made of the first conductive film formation film, and the second conductive film is made of the second conductive film formation film; implanting oxygen ions, nitrogen ions, or oxygen and nitrogen ions into an interface region between the first conductive film and the second conductive film, or the second conductive film by ion implantation, thereby forming an ion containing layer; and reacting oxygen, nitrogen, or oxygen and nitrogen contained in the ion containing layer with the silicon or the metal by heat treatment, thereby forming an insulating film. In the reacting, the resistive element including the first conductive film, the insulating film, and the second conductive film is formed.

According to the method of the fifth aspect of the present disclosure, the resistive element can be formed which includes the insulating film providing electrical isolation between the first conductive film containing the metal and the second conductive film containing silicon, or the insulating film providing electrical isolation between lower and upper parts of the second conductive film containing silicon. Therefore, the resistive element can be achieved which can provide a sufficient resistance.

In addition, the ion containing layer is formed by implanting ions into the interface region between the first and second conductive films, or the second conductive film, and then the insulating film is formed by utilizing the ion containing layer. Therefore, the first and second conductive film formation films can be successively formed. This prevents etching residue and mask residue from being interposed between the first and second conductive film formation films.

Furthermore, the thickness of the insulating film (in other words, the thickness of a portion of the second conductive film which will be used as the insulating film) can be controlled by adjusting the ion implantation conditions for the ion containing layer formation layer and adjusting the heat treatment conditions for the insulating film. Since the thickness of the second conductive film of the resistive element can, therefore, be controlled, the resistance of the resistive element can be controlled without changing an interconnect pattern.

The method of the fifth aspect of the present disclosure preferably further includes: before the forming the first conductive film formation film, forming a gate insulating film formation film on a portion of the semiconductor substrate corresponding to the MISFET region; and after the forming the second conductive film formation film, sequentially patterning portions of the second conductive film formation film, the first conductive film formation film, and the gate insulating film formation film corresponding to the MISFET region, thereby sequentially forming a gate insulating film made of the gate insulating film formation film, and a gate electrode on the semiconductor substrate, where the gate electrode includes a third conductive film made of the first conductive film formation film and a fourth conductive film made of the second conductive film formation film. The sequentially patterning the portions corresponding to the resistive element region and the sequentially patterning the portions corresponding to the MISFET region are preferably simultaneously performed.

As described above, since neither of etching residue and mask residue is, thus, interposed between the first and second conductive film formation films, this prevents poor patterning of the gate electrode. In addition, since neither of etching residue and mask residue is interposed between the third and fourth conductive films, this prevents the interface resistance between the third and fourth conductive films from increasing, and prevents variations in the interface resistance. Such prevention can avoid deterioration of the characteristics of the MISFET.

In view of the above, the resistive element which can provide a sufficient resistance can be achieved without causing poor patterning of the gate electrode and deterioration of the characteristics of the MISFET.

Furthermore, the films formed on the semiconductor substrate are patterned, and then the ion containing layer is formed. Therefore, the structure of the resistive element region immediately before the patterning can be identical with that of the MISFET region immediately before the patterning. In other words, immediately before the patterning, no ion containing layer formation layer is interposed between portions of the first and second conductive film formation films corresponding to the resistive element region, or between lower and upper parts of a portion of the second conductive film formation film corresponding thereto. This can facilitate the patterning.

As described above, according to the semiconductor device of the present disclosure and the method for fabricating the same, the resistive element which can provide a sufficient resistance can be achieved without causing poor patterning of the gate electrode and deterioration of the characteristics of the MISFET.

### BRIEF DESCRIPTION OF THE DRAWINGS

FIGS. 1A-1D are cross-sectional views illustrating process steps in a method for fabricating a semiconductor device according to a first embodiment of the present disclosure in a sequential order.

FIGS. 2A-2C are cross-sectional views illustrating other process steps in the method for fabricating a semiconductor device according to the first embodiment of the present disclosure in a sequential order.

FIGS. 3A-3C are cross-sectional views illustrating yet other process steps in the method for fabricating a semiconductor device according to the first embodiment of the present disclosure in a sequential order.

FIGS. 4A-4C are cross-sectional views illustrating further process steps in the method for fabricating a semiconductor device according to the first embodiment of the present disclosure in a sequential order.

FIGS. 5A-5D are cross-sectional views illustrating process steps in a method for fabricating a semiconductor device according to a second embodiment of the present disclosure in a sequential order.

FIGS. 6A-6D are cross-sectional views illustrating other process steps in the method for fabricating a semiconductor device according to the second embodiment of the present disclosure in a sequential order.

FIGS. 7A-7C are cross-sectional views illustrating process steps in a method for fabricating a semiconductor device according to a third embodiment of the present disclosure in a sequential order.

FIGS. 8A-8C are cross-sectional views illustrating other process steps in the method for fabricating a semiconductor device according to the third embodiment of the present disclosure in a sequential order.

FIG. 9 is a cross-sectional view illustrating the structure of a conventional semiconductor device.

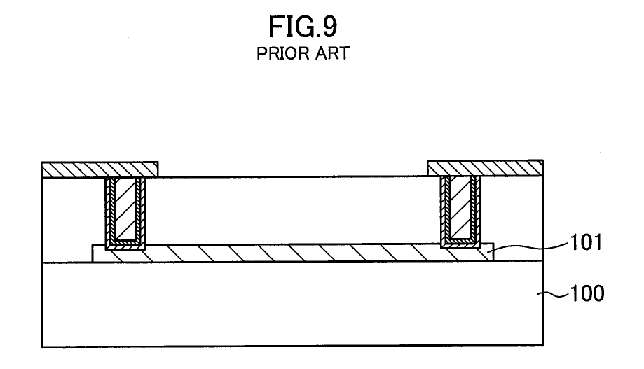

### DETAILED DESCRIPTION

### First Embodiment

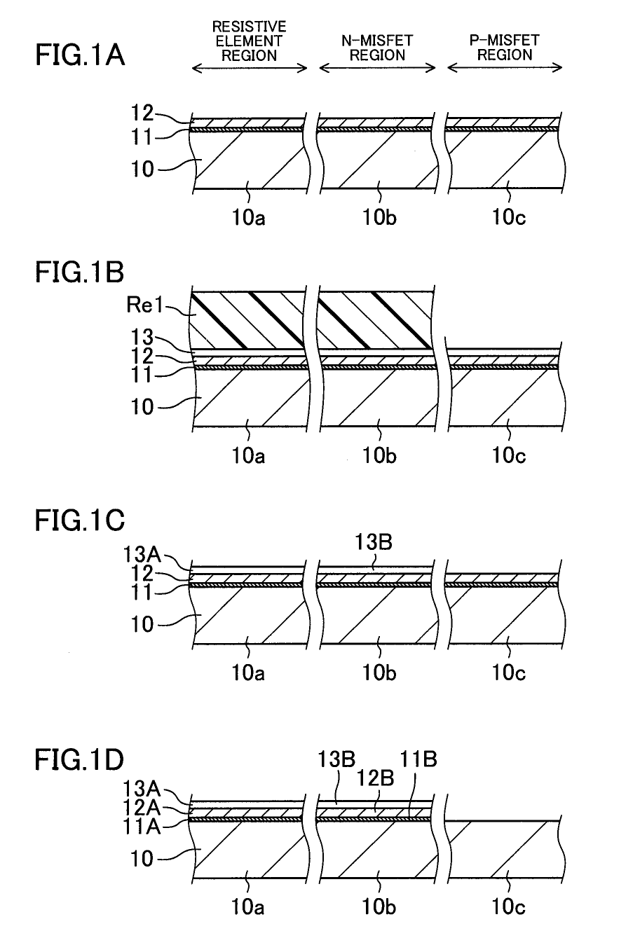

A method for fabricating a semiconductor device according to a first embodiment of the present disclosure will be described hereinafter with reference to FIGS. 1A-4C. FIGS. 1A-4C are cross-sectional views illustrating process steps in the method for fabricating a semiconductor device according to the first embodiment of the present disclosure in a sequential order. A “resistive element region” is illustrated on the left side of each of FIGS. 1A-4C, an “n-MISFET region” is illustrated in the middle thereof, and a “p-MISFET region” is illustrated on the right side thereof. The “resistive element region” denotes a region where a resistive element is to be formed, the “n-MISFET region” denotes a region where an n-MISFET is to be formed, and the “p-MISFET region” denotes a region where a p-MISFET is to be formed.

First, as illustrated in FIG. 1A, e.g., a 2-nm-thick first gate insulating film formation film 11 is deposited, e.g., by atomic layer deposition (ALD) or physical vapor deposition (PVD) to cover a resistive element portion 10a, an n-MISFET portion 10b, and a p-MISFET portion 10c of a semiconductor substrate 10. A high-dielectric-constant film, such as an oxide film containing hafnium (Hf) and lanthanum (La), is used as the first gate insulating film formation film 11.

Thereafter, e.g., a 20-nm-thick first conductive film formation film 12 containing metal is deposited on the first gate insulating film formation film 11, e.g., by PVD. A refractory metal film, such as a tantalum carbide film (TaC film), is used as the first conductive film formation film 12.

Next, as illustrated in FIG. 1B, e.g., a 15-nm-thick first insulating film formation film 13 made of SiO₂ is deposited on the first conductive film formation film 12, e.g., by chemical vapor deposition (CVD). Then, a photoresist pattern Re1 is formed on the first insulating film formation film 13 by photolithography to cover the resistive element region and the n-MISFET region and expose the p-MISFET region.

Next, as illustrated in FIG. 1C, a portion of the first insulating film formation film 13 corresponding to the p-MISFET region is removed by etching using, e.g., a hydrofluoric acid solution and using the photoresist pattern Re1 as a mask. Then, the photoresist pattern Re1 is removed, e.g., by ashing using radicals generated by H₂/N₂ mixed gas plasma.

Thus, a first insulating film formation film 13A is formed on a portion of the first conductive film formation film 12 corresponding to the resistive element region, and a first insulating film formation film 13B is formed on a portion of the first conductive film formation film 12 corresponding to the n-MISFET region.

Next, as illustrated in FIG. 1D, a portion of the first conductive film formation film 12 corresponding to the p-MISFET region and a portion of the first gate insulating film formation film 11 corresponding thereto are sequentially removed, e.g., by etching using a hydrofluoric acid solution and a sulfuric acid-hydrogen peroxide solution and using the first insulating film formation films 13A and 13B as masks.

Thus, a first gate insulating film formation film 11A, a first conductive film formation film 12A, and the first insulating film formation film 13A are sequentially formed on the resistive element portion 10a of the semiconductor substrate 10. A first gate insulating film formation film 11B, a first conductive film formation film 12B, and the first insulating film formation film 13B are sequentially formed on the n-MISFET portion 10b of the semiconductor substrate 10.

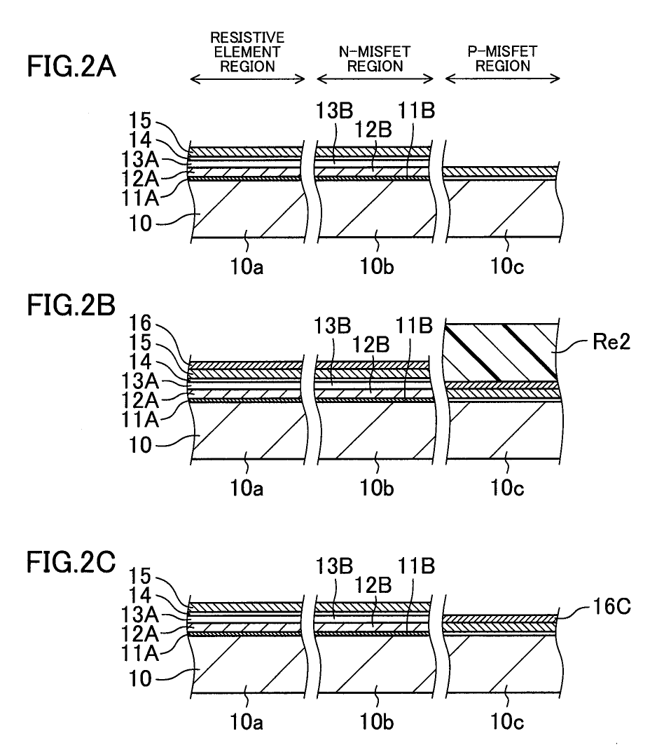

Next, as illustrated in FIG. 2A, e.g., a 2-nm-thick second gate insulating film formation film 14 is deposited, e.g., by ALD or PVD to cover the first insulating film formation films 13A and 13B and the p-MISFET portion 10c of the semiconductor substrate 10. A high-dielectric-constant film, such as an oxide film containing Hf and aluminum (Al), is used as the second gate insulating film formation film 14.

Thereafter, e.g., a 20-nm-thick second conductive film formation film 15 containing metal is deposited on the second gate insulating film formation film 14, e.g., by PVD. A refractory metal film, such as a titanium nitride (TiN) film, is used as the second conductive film formation film 15.

Next, as illustrated in FIG. 2B, e.g., a 10-nm-thick second insulating film formation film 16 made of SiO₂ is deposited on the second conductive film formation film 15, e.g., by CVD. Then, a photoresist pattern Re2 is formed on the second insulating film formation film 16 by photolithography to expose the resistive element region and the n-MISFET region and cover the p-MISFET region.

Next, as illustrated in FIG. 2C, a portion of the second insulating film formation film 16 covering the resistive element region and the n-MISFET region is removed, e.g., by etching using a hydrofluoric acid solution and using the photoresist pattern Re2 as a mask. Then, the photoresist pattern Re2 is removed, e.g., by ashing using radicals generated by O₂/N₂ mixed gas plasma.

Thus, a second insulating film formation film 16C is formed on a portion of the second conductive film formation film 15 corresponding to the p-MISFET region.

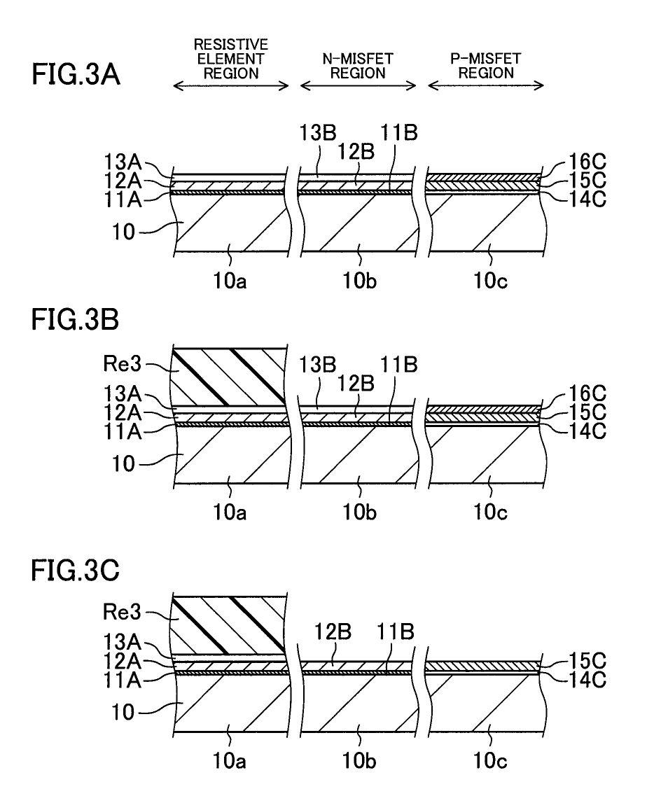

Next, as illustrated in FIG. 3A, a portion of the second conductive film formation film 15 covering the resistive element region and the n-MISFET region and a portion of the second gate insulating film formation film 14 covering these regions are sequentially removed, e.g., by etching using a hydrofluoric acid solution and a sulfuric acid-hydrogen peroxide solution and using the second insulating film formation film 16C as a mask.

In this way, a second gate insulating film formation film 14C, a second conductive film formation film 15C, and the second insulating film formation film 16C are sequentially formed on the p-MISFET portion 10c of the semiconductor substrate 10.

Next, as illustrated in FIG. 3B, a photoresist pattern Re3 is formed on the first insulating film formation film 13A by photolithography to cover the resistive element region and expose the n-MISFET region and the p-MISFET region.

Next, as illustrated in FIG. 3C, the first insulating film formation film 13B and the second insulating film formation film 16C are removed, e.g., by etching using a hydrofluoric acid solution and using the photoresist pattern Re3 as a mask. In this case, since the first and second insulating film formation films 13B and 16C are made of, e.g., SiO₂, this prevents a residue of the first insulating film formation film 13B from remaining on the first conductive film formation film 12B, and prevents a residue of the second insulating film formation film 16C from remaining on the second conductive film formation film 15C.

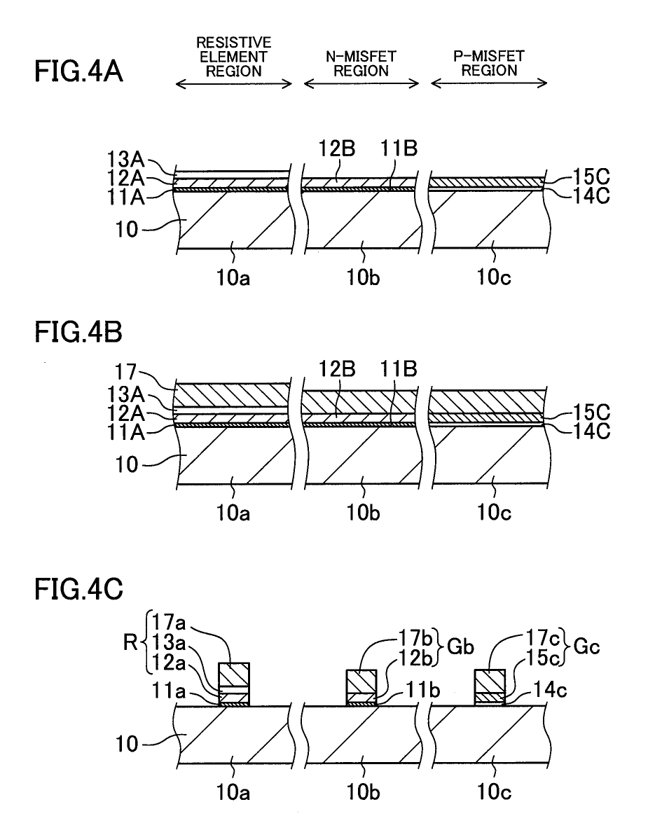

Next, as illustrated in FIG. 4A, the photoresist pattern Re3 is removed, e.g., by ashing using radicals generated by O₂/N₂ mixed gas plasma.

Next, as illustrated in FIG. 4B, e.g., a 100-nm-thick third conductive film formation film 17 containing silicon is deposited, e.g., by CVD to cover the first insulating film formation film 13A, the first conductive film formation film 12B, and the second conductive film formation film 15C. For example, a polysilicon film is used as the third conductive film formation film 17.

Next, as illustrated in FIG. 4C, a photoresist pattern (not illustrated) is formed on the third conductive film formation film 17 by photolithography. Then, the third conductive film formation film 17, the first insulating film formation film 13A, a combination of the first conductive film formation films 12A and 12B and the second conductive film formation film 15C, and a combination of the first gate insulating film formation films 11A and 11B and the second gate insulating film formation film 14C are sequentially patterned by dry etching using the photoresist pattern as a mask. Thus, a resistive element R including a lower conductive film 12a, an insulating film 13a, and an upper conductive film 17a is formed on the resistive element portion 10a of the semiconductor substrate 10 with an insulating film 11a interposed between the resistive element R and the resistive element portion 10a. A gate insulating film 11b, and a gate electrode Gb including a lower conductive film 12b and an upper conductive film 17b are sequentially formed on the n-MISFET portion 10b of the semiconductor substrate 10. A gate insulating film 14c, and a gate electrode Gc including a lower conductive film 15c and an upper conductive film 17c are sequentially formed on the p-MISFET portion 10c of the semiconductor substrate 10. Thus, an interconnect is formed simultaneously with the gate electrodes Gb and Gc, and this interconnect is utilized as the resistive element R.

Thereafter, process steps similar to those in a method for fabricating a semiconductor device including a normal MIS transistor are performed. Specifically, sidewalls, source/drain regions, a silicide film, and other films are formed.

In the above-described manner, a semiconductor device according to this embodiment can be fabricated.

In this embodiment, as illustrated in FIG. 1C, the first insulating film formation film (in other words, the hard mask) 13B is formed on the first conductive film formation film 12 to cover the n-MISFET region. Then, as illustrated in FIG. 3C, the first insulating film formation film 13B is removed. In this case, since the first insulating film formation film 13B is, e.g., a SiO₂ film rather than a photoresist film, an anti-reflective film, or another film, this prevents a residue of the first insulating film formation film 13B from remaining on the first conductive film formation film 12B. Therefore, after the deposition of the third conductive film formation film 17 as illustrated in FIG. 4B, no residue of the first insulating film formation film 13B is interposed between the first conductive film formation film 12B and the third conductive film formation film 17.

Likewise, in this embodiment, as illustrated in FIG. 2C, the second insulating film formation film (in other words, the hard mask) 16C is formed on the second conductive film formation film 15 to cover the p-MISFET region. Then, as illustrated in FIG. 3C, the second insulating film formation film 16C is removed. In this case, since the second insulating film formation film 16C is, e.g., a SiO₂ film rather than a photoresist film, an anti-reflective film, or another film, this prevents a residue of the second insulating film formation film 16C from remaining on the second conductive film formation film 15C. Therefore, after the deposition of the third conductive film formation film 17 as illustrated in FIG. 4B, no residue of the second insulating film formation film 16C is interposed between the second conductive film formation film 15C and the third conductive film formation film 17.

In contrast, when, instead of an insulating film formation film made of SiO₂, e.g., a photoresist film or an organic anti-reflective film is deposited on a conductive film formation film for forming a lower conductive film (hereinafter referred to as the “lower conductive film formation film”), this causes the following concerns. Since a residue of the photoresist film or the organic anti-reflective film remains on the lower conductive film formation film after removal of the photoresist film or the organic anti-reflective film, the residue of the photoresist film or the organic anti-reflective film is interposed between the lower conductive film formation film and a conductive film formation film for forming an upper conductive film. Such residue may cause poor patterning of the gate electrode. Furthermore, such residue may increase the interface resistance between a portion of a lower conductive film corresponding to both of an n-MISFET and a p-MISFET, and a portion of an upper conductive film corresponding thereto; and/or may cause variations in the interface resistance, leading to deterioration of the characteristics of the n-MISFET and the p-MISFET.

The structure of a semiconductor device according to the first embodiment of the present disclosure will be described hereinafter with reference to FIG. 4C.

The semiconductor device according to this embodiment includes a resistive element R, an n-MISFET including a gate electrode Gb, and a p-MISFET including a gate electrode Gc as illustrated in FIG. 4C.

The resistive element R includes a lower conductive film (first conductive film) 12a formed on a resistive element portion 10a of a semiconductor substrate 10 and containing metal, an insulating film 13a formed on the lower conductive film 12a, and an upper conductive film (second conductive film) 17a formed on the insulating film 13a and containing silicon. The insulating film 13a provides electrical isolation between the lower conductive film 12a and the upper conductive film 17a.

The n-MISFET includes a gate insulating film 11b and a gate electrode Gb. The gate insulating film 11b is formed on an n-MISFET portion 10b of the semiconductor substrate 10. The gate electrode Gb includes a lower conductive film (third conductive film) 12b formed on the gate insulating film 11b, and an upper conductive film (fourth conductive film) 17b formed on the lower conductive film 12b. In contrast, the p-MISFET includes a gate insulating film 14c and a gate electrode Gc. The gate insulating film 14c is formed on a p-MISFET portion 10c of the semiconductor substrate 10. The gate electrode Gc includes a lower conductive film 15c formed on the gate insulating film 14c, and an upper conductive film 17c formed on the lower conductive film 15c.

The material of the lower conductive film 12a of the resistive element R is identical with that of the lower conductive film 12b of the n-MISFET. The material of the upper conductive film 17a of the resistive element R is identical with that of the upper conductive film 17b of the n-MISFET and that of the upper conductive film 17c of the p-MISFET.

The material of the gate insulating film 11b of the n-MISFET (e.g., an oxide containing Hf and La) is different from that of the gate insulating film 14c of the p-MISFET (e.g., an oxide containing Hf and Al). The material of the lower conductive film 12b of the n-MISFET (e.g., TaC) is different from that of the lower conductive film 15c of the p-MISFET (e.g., TiN).

An insulating film 11a is interposed between the semiconductor substrate 10 and the resistive element R. The material of the insulating film 11a is identical with that of the gate insulating film 11b of the n-MISFET.

According to this embodiment, the resistive element R can be formed which includes the insulating film 13a providing electrical isolation between the lower conductive film 12a and the upper conductive film 17a. This allows the resistive element R to provide a sufficient resistance.

According to this embodiment, no residue of the first insulating film formation film 13B is interposed between the first conductive film formation film 12B and the third conductive film formation film 17. This prevents poor patterning of the gate electrode Gb. Furthermore, no residue of the second insulating film formation film 16C is interposed between the second conductive film formation film 15C and the third conductive film formation film 17. This prevents poor patterning of the gate electrode Gc.

According to this embodiment, no residue of the first insulating film formation film 13B is interposed between the lower and upper conductive films 12b and 17b of the n-MISFET. Furthermore, no residue of the second insulating film formation film 16C is interposed between the lower and upper conductive films 15c and 17c of the p-MISFET. This prevents the interface resistances between the lower and upper conductive films 12b and 17b of the n-MISFET and between the lower and upper conductive films 15c and 17c of the p-MISFET from increasing, and prevents variations in the interface resistances. Such prevention can avoid deterioration of the characteristics of the n-MISFET and the p-MISFET.

As described above, the resistive element R which can provide a sufficient resistance can be achieved without causing poor patterning of the gate electrodes Gb and Gc and deterioration of the characteristics of the n-MISFET and the p-MISFET.

Moreover, according to this embodiment, the material of the gate insulating film 11b of the n-MISFET is different from that of the gate insulating film 14c of the p-MISFET, and the material of the lower conductive film 12b of the gate electrode Gb of the n-MISFET is different from that of the lower conductive film 15c of the gate electrode Gc of the p-MISFET. Therefore, the characteristics of the n-MISFET and the characteristics of the p-MISFET can be separately controlled.

In the first embodiment, e.g., a 15-nm-thick SiO₂ film is used as the insulating film 13a of the resistive element R. However, the insulating film 13a is not limited to the above-described material and thickness.

For example, the following films may be used as the insulating film 13a:

(1) an oxide film containing Hf, zirconium (Zr), La, Al, lutetium (Lu), or gadolinium (Gd);

(2) a nitride film containing Hf, Zr, La, Al, Lu, Gd, or Si;

(3) an oxynitride film containing Hf, Zr, La, Al, Lu, Gd, or Si.

The thickness of the insulating film 13a varies according to the breakdown voltage of the material itself of the insulating film 13a, the voltage to be applied to the resistive element R at the time of actuation of the resistive element R, and other conditions. However, the insulating film 13a may have a thickness, e.g., in a range of approximately greater than or equal to 2 nm and less than or equal to 40 nm, and preferably has a thickness in a range of greater than or equal to 5 nm and less than or equal to 30 nm.

### Second Embodiment

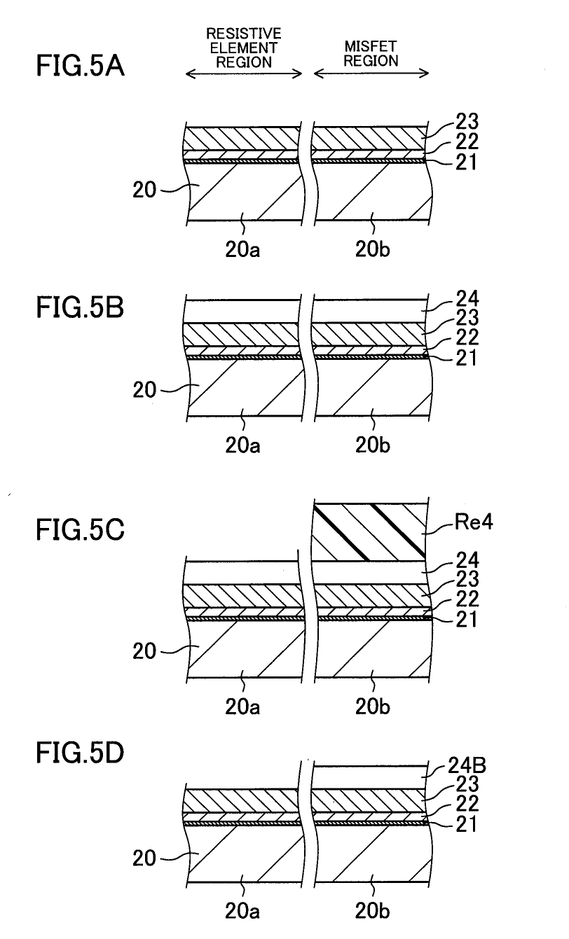

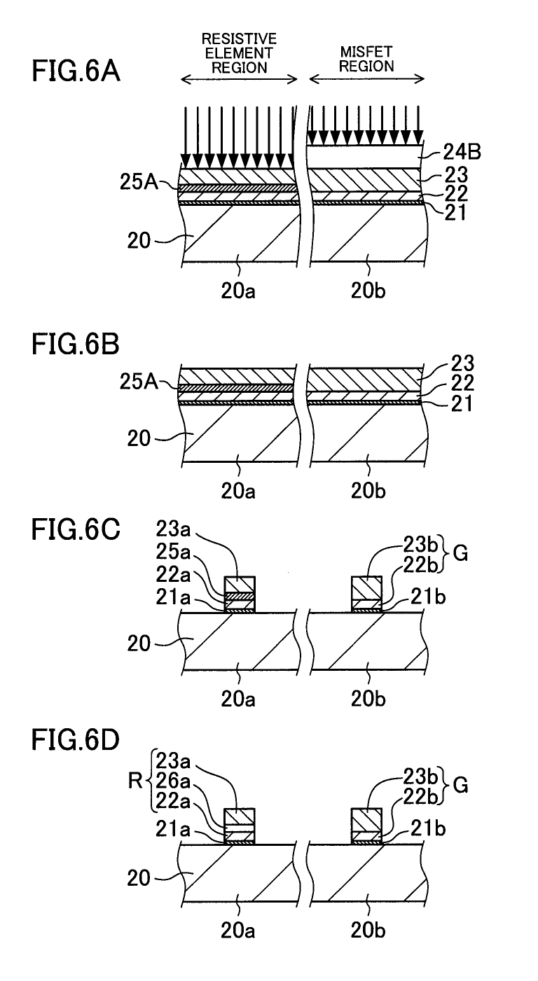

A method for fabricating a semiconductor device according to a second embodiment of the present disclosure will be described hereinafter with reference to FIGS. 5A-6D. FIGS. 5A-6D are cross-sectional views illustrating process steps in the method for fabricating a semiconductor device according to the second embodiment of the present disclosure in a sequential order. A “resistive element region” is illustrated on the left side of each of FIGS. 5A-6D and FIG. 7A-8C which will be described below, a “MISFET region” is illustrated on the right side thereof. The “MISFET region” denotes a region where an n-MISFET or a p-MISFET is to be formed. In this embodiment and a third embodiment described below, the material of a gate insulating film of such an n-MISFET is identical with that of a gate insulating film of such a p-MISFET, and the material of a third conductive film of a gate electrode of the n-MISFET is identical with that of a third conductive film of a gate electrode of the p-MISFET. Therefore, only one of the n-MISFET and the p-MISFET is illustrated in FIGS. 5A-6D and FIGS. 7A-8C which will be described below, and the other MISFET is not illustrated.

First, as illustrated in FIG. 5A, e.g., a 2-nm-thick gate insulating film formation film 21 is deposited, e.g., by ALD to cover a resistive element portion 20a and a MISFET portion 20b of a semiconductor substrate 20. A high-dielectric-constant film, such as an oxide film containing Hf, is used as the gate insulating film formation film 21.

Thereafter, e.g., a 20-nm-thick first conductive film formation film 22 containing metal is deposited on the gate insulating film formation film 21, e.g., by PVD. A refractory metal film, such as a TiN film, is used as the first conductive film formation film 22.

Thereafter, e.g., a 70-nm-thick second conductive film formation film 23 containing silicon is deposited on the first conductive film formation film 22, e.g., by CVD. For example, a polysilicon film is used as the second conductive film formation film 23.

Next, as illustrated in FIG. 5B, e.g., a 100-nm-thick hard mask formation film 24 made of SiO₂ is deposited on the second conductive film formation film 23, e.g., by CVD.

Next, as illustrated in FIG. 5C, a photoresist pattern Re4 is formed on the hard mask formation film 24 by photolithography to expose the resistive element region and cover the MISFET region.

Next, as illustrated in FIG. 5D, a portion of the hard mask formation film 24 corresponding to the resistive element region is removed, e.g., by etching using a hydrofluoric acid solution and using the photoresist pattern Re4 as a mask. Then, the photoresist pattern Re4 is removed, e.g., by ashing using radicals generated by O₂/N₂ mixed gas plasma.

Thus, a hard mask 24B is formed to cover a portion of the second conductive film formation film 23 corresponding to the MISFET region.

Next, as illustrated in FIG. 6A, for example, oxygen ions are implanted into an interface region between the first conductive film formation film 22 and the second conductive film formation film 23 by ion implantation using the hard mask 24B, e.g., at an implantation energy of 20 keV and a dose of 5×10¹⁵ ions/cm². Thus, an ion containing layer formation layer 25A containing oxygen ions is formed between a portion of the first conductive film formation film 22 corresponding to the resistive element region and a portion of the second conductive film formation film 23 corresponding thereto.

Next, as illustrated in FIG. 6B, the hard mask 24B is removed, e.g., by etching using a hydrofluoric acid solution.

Next, a photoresist pattern (not illustrated) is formed on the second conductive film formation film 23 by photolithography. Then, the second conductive film formation film 23, the ion containing layer formation layer 25A, the first conductive film formation film 22, and the gate insulating film formation film 21 are sequentially patterned by dry etching using the photoresist pattern as a mask. Thus, as illustrated in FIG. 6C, an insulating film 21a, a first conductive film (lower conductive film) 22a, an ion containing layer 25a, and a second conductive film (upper conductive film) 23a are sequentially formed on the resistive element portion 20a of the semiconductor substrate 20, and a gate insulating film 21b, and a gate electrode G including a third conductive film (lower conductive film) 22b and a fourth conductive film (upper conductive film) 23b are sequentially formed on the MISFET portion 20b of the semiconductor substrate 20.

Next, the entire surface region of the semiconductor substrate 20 is annealed at 800° C., e.g., with an electric furnace, or by lamp annealing or laser annealing. Thus, oxygen and silicon both contained in the ion containing layer 25a are bonded together, thereby forming an insulating film 26a made of an oxide containing silicon, such as SiO₂, as illustrated in FIG. 6D. The insulating film 26a is substantially parallel to the principal surface of the semiconductor substrate 20, the first conductive film 22a, and the second conductive film 23a. Here, the “principal surface of the semiconductor substrate 20” denotes the surface of the semiconductor substrate 20 on which a resistive element R is to be formed.

Thus, a resistive element R is formed which includes the first conductive film 22a, the insulating film 26a, and the second conductive film 23a.

Then, process steps similar to those in a method for fabricating a semiconductor device including a normal MIS transistor are performed.

In the above-described manner, a semiconductor device according to this embodiment can be fabricated.

The structure of a semiconductor device according to the second embodiment of the present disclosure will be described hereinafter with reference to FIG. 6D.

The semiconductor device according to this embodiment includes a resistive element R, and a MISFET including a gate electrode G as illustrated in FIG. 6D.

The resistive element R includes a first conductive film 22a formed on a resistive element portion 20a of a semiconductor substrate 20 and containing metal, an insulating film 26a formed on the first conductive film 22a, and a second conductive film 23a formed on the insulating film 26a and containing silicon. The insulating film 26a provides electrical isolation between the first conductive film 22a and the second conductive film 23a.

The MISFET includes a gate insulating film 21b and a gate electrode G. The gate insulating film 21b is formed on a MISFET portion 20b of the semiconductor substrate 20. The gate electrode G includes a third conductive film 22b formed on the gate insulating film 21b, and a fourth conductive film 23b formed on the third conductive film 22b.

The material of the first conductive film 22a is identical with that of the third conductive film 22b. The material of the second conductive film 23a is identical with that of the fourth conductive film 23b.

The insulating film 26a is an oxide film containing silicon contained in the second conductive film 23a.

An insulating film 21a is interposed between the semiconductor substrate 20 and the resistive element R. The material of the insulating film 21a is identical with that of the gate insulating film 21b.

According to this embodiment, the resistive element R can be formed which includes the insulating film 26a providing electrical isolation between the first conductive film 22a and the second conductive film 23a. Therefore, the resistive element R can be achieved which can provide a sufficient resistance.

According to this embodiment, the ion containing layer formation layer 25A is formed by implanting oxygen ions into the interface region between the first conductive film formation film 22 and the second conductive film formation film 23 as illustrated in FIG. 6A, and then, as illustrated in FIG. 6D, the insulating film 26a is formed by utilizing the ion containing layer formation layer 25A. Thus, as illustrated in FIG. 5A, the first conductive film formation film 22 and the second conductive film formation film 23 can be successively deposited. Since neither of etching residue and mask residue is, therefore, interposed between the first conductive film formation film 22 and the second conductive film formation film 23, this prevents poor patterning of the gate electrode G.

According to this embodiment, the first conductive film formation film 22 and the second conductive film formation film 23 can be successively deposited as illustrated in FIG. 5A. Since neither of etching residue and mask residue is, therefore, interposed between the third conductive film 22b and the fourth conductive film 23b, this prevents the interface resistance between the third conductive film 22b and the fourth conductive film 23b from increasing, and prevents variations in the interface resistance. Such prevention can avoid deterioration of the characteristics of the MISFET.

As described above, the resistive element R which can provide a sufficient resistance can be achieved without causing poor patterning of the gate electrode G and deterioration of the characteristics of the MISFET.

Furthermore, according to this embodiment, the thickness of the insulating film 26a (in other words, the thickness of a portion of the second conductive film 23a which will be used as the insulating film 26a) can be controlled by adjusting the ion implantation conditions in the process step illustrated in FIG. 6A and adjusting the annealing conditions in the process step illustrated in FIG. 6D. Since the thickness of the second conductive film 23a of the resistive element R can, therefore, be controlled, the resistance of the resistive element R can be controlled without changing an interconnect pattern.

In the second embodiment, the following case was described as a specific example. Specifically, as illustrated in FIG. 6A, oxygen ions are implanted into the interface region between the first conductive film formation film 22 and the second conductive film formation film 23 by ion implantation, thereby forming the ion containing layer formation layer 25A containing oxygen ions. Then, as illustrated in FIG. 6D, the insulating film 26a made of an oxide containing silicon is formed by annealing. However, the present disclosure is not limited to the above-described case. First, for example, nitrogen ions may be implanted into the interface region between the first conductive film formation film and the second conductive film formation film by ion implantation, thereby forming an ion containing layer formation layer containing nitrogen ions. Then, an insulating film made of a nitride containing silicon may be formed by annealing. Second, for example, oxygen ions and nitrogen ions may be implanted into the interface region between the first conductive film formation film and the second conductive film formation film by ion implantation, thereby forming an ion containing layer formation layer containing oxygen ions and nitrogen ions. Then, an insulating film made of an oxynitride containing silicon may be formed by annealing.

In the second embodiment, the case in which the insulating film 26a made of an oxide containing silicon contained in the second conductive film formation film 23 is formed was described as a specific example. However, the present disclosure is not limited to this case. For example, an insulating film made of an oxide containing metal contained in the first conductive film formation film 22 may be formed.

### Third Embodiment

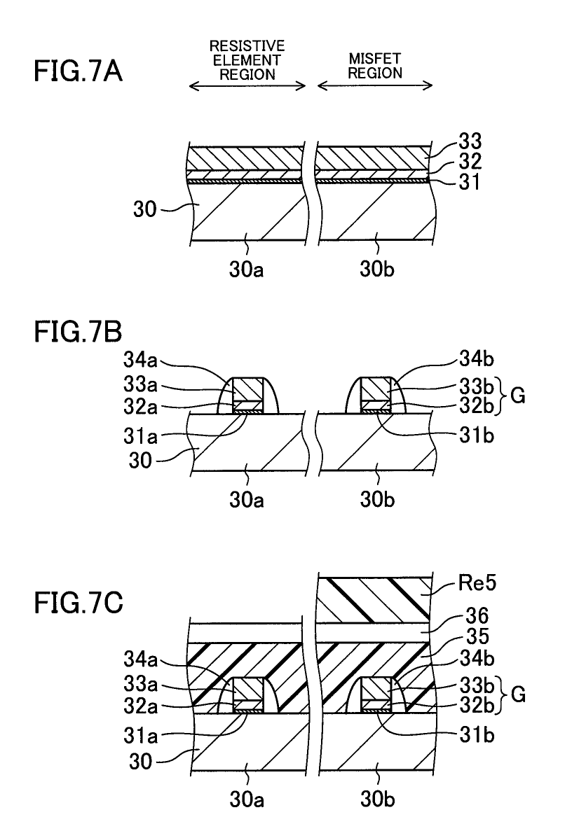

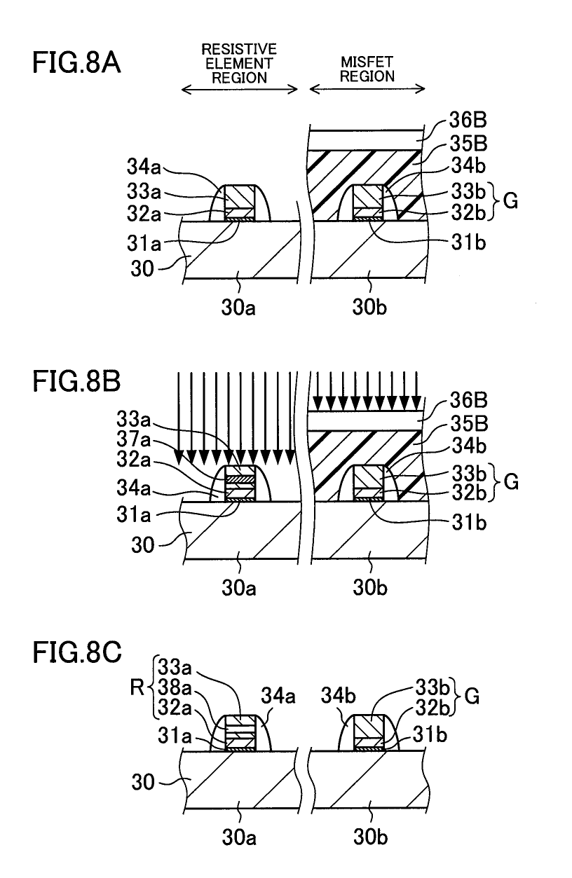

A method for fabricating a semiconductor device according to a third embodiment of the present disclosure will be described hereinafter with reference to FIGS. 7A-8C. FIGS. 7A-8C are cross-sectional views illustrating process steps in the method for fabricating a semiconductor device according to the third embodiment of the present disclosure in a sequential order.

First, as illustrated in FIG. 7A, e.g., a 2-nm-thick gate insulating film formation film 31 is deposited, e.g., by ALD to cover a resistive element portion 30a and a MISFET portion 30b of a semiconductor substrate 30. For example, a high-dielectric-constant film, such as an oxide film containing Hf, is used as the gate insulating film formation film 31.

Thereafter, e.g., a 20-nm-thick first conductive film formation film 32 containing metal is deposited on the gate insulating film formation film 31, e.g., by PVD. A refractory metal film, such as a TiN film, is used as the first conductive film formation film 32.

Thereafter, e.g., a 70-nm-thick second conductive film formation film 33 containing silicon is deposited on the first conductive film formation film 32, e.g., by CVD. For example, a polysilicon film is used as the second conductive film formation film 33.

Next, as illustrated in FIG. 7B, a photoresist pattern (not illustrated) is formed on the second conductive film formation film 33 by photolithography. Then, the second conductive film formation film 33, the first conductive film formation film 32, and the gate insulating film formation film 31 are sequentially patterned by dry etching using the photoresist pattern as a mask. Thus, an insulating film 31a, a first conductive film (lower conductive film) 32a, and a second conductive film (upper conductive film) 33a are sequentially formed on the resistive element portion 30a of the semiconductor substrate 30. A gate insulating film 31b, and a gate electrode G including a third conductive film (lower conductive film) 32b and a fourth conductive film (upper conductive film) 33b are sequentially formed on the MISFET portion 30b of the semiconductor substrate 30.

Thereafter, a sidewall formation film made of, e.g., silicon nitride (SiN) is formed, e.g., by CVD to cover the entire surface region of the semiconductor substrate 30. Then, the sidewall formation film is anisotropically etched. Thus, sidewalls 34a are formed on side surfaces of a combination of the insulating film 31a, the first conductive film 32a, and the second conductive film 33a, and sidewalls 34b are formed on side surfaces of a combination of the gate insulating film 31b, the third conductive film 32b, and the fourth conductive film 33b.

Thereafter, n-type (or p-type) impurity ions are implanted into the MISFET portion 30b of the semiconductor substrate 30 by ion implantation using the sidewalls 34b as masks. Thus, n-type (or p-type) source/drain regions (not illustrated) are formed in regions of the MISFET portion 30b located outside and below the sidewalls 34b in a self-aligned manner. When the conductivity type of a MISFET to be formed on a MISFET region is n-type, n-type impurity ions are implanted into the regions of the MISFET portion 30b. On the other hand, when the conductivity type of the MISFET is p-type, p-type impurity ions are implanted into the regions.

Next, as illustrated in FIG. 7C, a photoresist film 35 is deposited to cover the entire surface region of the semiconductor substrate 30. Then, e.g., a 100-nm-thick mask formation film 36 made of organic spin-on-glass (SOG) is deposited on the photoresist film 35, e.g., by spin coating. Then, a photoresist pattern Re5 is formed on the mask formation film 36 by photolithography to expose a resistive element region and cover the MISFET region.

Next, as illustrated in FIG. 8A, a portion of the mask formation film 36 corresponding to the resistive element region is removed, e.g., by plasma etching using a mixed gas containing a carbon tetrafluoride (CF₄) gas, an O₂ gas, and an argon (Ar) gas and using the photoresist pattern Re5 as a mask. Then, a portion of the photoresist film 35 corresponding to the resistive element region is removed, e.g., by ashing using radicals generated by O₂/N₂ mixed gas plasma. Then, the photoresist pattern Re5 is removed, e.g., by ashing using radicals generated by O₂/N₂ mixed gas plasma.

Thus, a photoresist film 35B and a mask 36B are sequentially formed on the MISFET portion 30b of the semiconductor substrate 30.

Next, as illustrated in FIG. 8B, e.g., oxygen ions are implanted into the second conductive film 33a by ion implantation using the mask 36B, e.g., at an implantation energy of 20 keV and a dose of 5×10¹⁵ ions/cm². Thus, an ion containing layer 37a containing oxygen ions is formed between lower and upper parts of the second conductive film 33a.

Next, as illustrated in FIG. 8C, the mask 36B is removed, e.g., by etching using a hydrofluoric acid solution. Then, the photoresist film 35B is removed, e.g., by aching using radicals generated by O₂/N₂ mixed gas plasma.

Thereafter, the entire surface region of the semiconductor substrate 30 is annealed at 800° C., e.g., with an electric furnace, or by lamp annealing or laser annealing. Thus, oxygen and silicon both contained in the ion containing layer 37a are bonded together, thereby forming an insulating film 38a made of an oxide containing silicon, such as SiO₂. The insulating film 38a is substantially parallel to the principal surface of the semiconductor substrate 30, the first conductive film 32a, and the second conductive film 33a. Here, the “principal surface of the semiconductor substrate 30” denotes the surface of the semiconductor substrate 30 on which a resistive element R is to be formed.

Thus, a resistive element R is formed which includes the first conductive film 32a, the insulating film 38a, and the second conductive film 33a.

In the above-described manner, a semiconductor device according to this embodiment can be fabricated.

The differences between the fabrication method of this embodiment and the fabrication method of the second embodiment will be described below.

In the second embodiment, the ion containing layer formation layer 25A is formed by ion implantation as illustrated in FIG. 6A, and then the films formed on the semiconductor substrate 30 are patterned as illustrated in FIG. 6C. Then, the insulating film 26a is formed by annealing as illustrated in FIG. 6D. In contrast, in this embodiment, the films formed on the semiconductor substrate 30 are patterned as illustrated in FIG. 7B, and the ion containing layer 37a is formed by ion implantation as illustrated in FIG. 8B. Then, the insulating film 38a is formed by annealing as illustrated in FIG. 8C.

The structure of a semiconductor device according to the third embodiment of the present disclosure will be described hereinafter with reference to FIG. 8C.

The semiconductor device according to this embodiment includes a resistive element R and a MISFET including a gate electrode G as illustrated in FIG. 8C.

The resistive element R includes a first conductive film 32a formed on a resistive element portion 30a of a semiconductor substrate 30 and containing metal, a second conductive film 33a formed on the first conductive film 32a and containing silicon, and an insulating film 38a formed between lower and upper parts of the second conductive film 33a. The insulating film 38a provides electrical isolation between the lower and upper parts of the second conductive film 33a.

The MISFET includes a gate insulating film 31b and the gate electrode G. The gate insulating film 31b is formed on a MISFET portion 30b of the semiconductor substrate 30. The gate electrode G includes a third conductive film 32b formed on the gate insulating film 31b, and a fourth conductive film 33b formed on the third conductive film 32b.

The material of the first conductive film 32a is identical with that of the third conductive film 32b. The material of the second conductive film 33a is identical with that of the fourth conductive film 33b.

The insulating film 38a is an oxide film containing silicon contained in the second conductive film 33a.

An insulating film 31a is interposed between the semiconductor substrate 30 and the resistive element R. The material of the insulating film 31a is identical with that of the gate insulating film 31b.

The differences between the structure of the semiconductor device of this embodiment and that of the semiconductor device of the second embodiment will be described below.

In the second embodiment, as illustrated in FIG. 6A, the ion containing layer formation layer 25A is formed between the first conductive film formation film 22 and the second conductive film formation film 23. Therefore, the insulating film 26a is formed between the first conductive film 22a and the second conductive film 23a as illustrated in FIG. 6D. In contrast, in this embodiment, as illustrated in FIG. 8B, the ion containing layer 37a is formed between the lower and upper parts of the second conductive film 33a rather than between the first conductive film 32a and the second conductive film 33a. Therefore, the insulating film 38a is formed between the lower and upper parts of the second conductive film 33a as illustrated in FIG. 8C.

According to this embodiment, advantages similar to those in the second embodiment can be provided.

Furthermore, according to this embodiment, the films formed on the semiconductor substrate 30 are patterned as illustrated in FIG. 7B, and then the ion containing layer 37a is formed as illustrated in FIG. 8B. Therefore, as illustrated in FIG. 7B, the structure of the resistive element region immediately before the patterning can be identical with that of the MISFET region immediately before the patterning. In other words, immediately before the patterning, no ion containing layer formation layer is interposed between lower and upper parts of a portion of the second conductive film formation film 33 corresponding to the resistive element region. This can facilitate the patterning.

In the third embodiment, the following case was described as a specific example. Specifically, as illustrated in FIG. 8B, the ion containing layer 37a containing oxygen ions is formed by ion implantation, and then the insulating film 38a made of an oxide containing silicon is formed by annealing as illustrated in FIG. 8C. However, the present disclosure is not limited to this case. First, for example, an ion containing layer containing nitrogen ions instead of oxygen ions may be formed by ion implantation, and then an insulating film made of a nitride containing silicon may be formed by annealing. Second, for example, an ion containing layer containing oxygen ions and nitrogen ions may be formed by ion implantation, and then an insulating film made of an oxynitride containing silicon may be formed by annealing.

In the third embodiment, the case in which, as illustrated in FIG. 8C, the insulating film 38a made of an oxide containing silicon contained in the second conductive film 33a is formed between the lower and upper parts of the second conductive film 33a was described as a specific example. However, the present disclosure is not limited to this case. For example, an insulating film made of an oxide containing silicon contained in the second conductive film, or an insulating film made of an oxide containing metal contained in the first conductive film may be formed between the first conductive film and the second conductive film.

In the first embodiment, e.g., a 20-nm-thick TaC film and a 20-nm-thick TiN film are used as conductive film formation films for forming lower conductive films (the first and second conductive film formation films 12 and 15). In the second and third embodiments, e.g., 20-nm-thick TiN films are used as the conductive film formation films for forming lower conductive films (the first conductive film formation films 22 and 32). However, these films are not limited to the above-described materials and thickness.

For example, any one of the following films (1)-(5) may be used as each of the conductive film formation films for forming lower conductive films:

(1) a metal film containing at least one metal selected from the group of metals including Al, iron (Fe), copper (Cu), nickel (Ni), cobalt (Co), titanium (Ti), tantalum (Ta), niobium (Nb), tungsten (W), molybdenum (Mo), vanadium (V), platinum (Pt), and gold (Au);

(2) a nitride film (e.g., a TiN film) containing at least one metal selected from the group of the metals;

(3) a carbide film (e.g., a TaC film or a tungsten carbide (WC) film) containing at least one metal selected from the group of the metals;

(4) a film of a silicon compound (hereinafter referred to the “silicon compound film”) containing at least one metal selected from the group of the metals; and

(5) an oxynitride film (e.g., a tantalum carbide oxynitride (TaCNO) film) containing at least one metal selected from the group of the metals.

For example, the thickness of each of the conductive film formation films varies according to the material thereof and other conditions. However, the conductive film formation film may have a thickness in a range of approximately greater than or equal to 5 nm and less than or equal to 100 nm, and preferably has a thickness in a range of greater than or equal to 10 nm and less than or equal to 70 nm.

In the first embodiment, e.g., a 100-nm-thick polysilicon film is used as the conductive film formation film for forming an upper conductive film, and in the second and third embodiments, e.g., a 70-nm-thick polysilicon film is used thereas (in the first embodiment, the third conductive film formation film 17; in the second embodiment, the second conductive film formation film 23; and in the third embodiment, the second conductive film formation film 33). However, the conductive film formation film is not limited to the above-described material and thickness.

For example, an amorphous silicon film or a monocrystalline silicon film may be used as the conductive film formation film for forming an upper conductive film.

For example, the lower limit of the thickness of the conductive film formation film meets the following requirements (1) and (2) and other requirements:

(1) the requirement to prevent ions from penetrating through the upper conductive film of the gate electrode after ion implantation for forming source/drain regions; and

(2) the requirement to prevent the entire upper conductive film of the gate electrode from being silicided after annealing for forming a silicide film.

Furthermore, for example, the upper limit of the thickness of the conductive film formation film meets the requirement to prevent poor filling of the space between adjacent gate electrodes due to a high aspect ratio between the adjacent gate electrodes after the filling of the space therebetween, and other requirements.

The thickness of the conductive film formation film varies according to the corresponding device rule and other conditions. However, the conductive film formation film may have a thickness in a range of approximately greater than or equal to 40 nm and less than or equal to 300 nm, and preferably has a thickness in a range of greater than or equal to 50 nm and less than or equal to 200 nm.

In the present disclosure, an interconnect including the first conductive film (lower conductive film) containing metal, the insulating film, and the second conductive film (upper conductive film) containing silicon is used as the resistive element. However, the interconnect can be also used as a fuse.

As described above, the present disclosure can implement a resistive element which can provide a sufficient resistance without causing poor patterning of the gate electrodes and deterioration of the characteristics of a MISFET. Therefore, the present disclosure is useful for semiconductor devices each including a resistive element and a MISFET with a gate electrode containing metal, and methods for fabricating the same.

What is claimed is:

1. A semiconductor device comprising:
a resistive element; and
a MISFET,
wherein the resistive element includes
a first conductive film formed on a semiconductor substrate and containing a metal;
a second conductive film formed on the first conductive film and containing silicon; and
an insulating film formed between the first conductive film and the second conductive film.

2. The semiconductor device of claim 1, wherein
the MISFET includes
a gate insulating film formed on the semiconductor substrate; and
a gate electrode including a third conductive film formed on the gate insulating film, and a fourth conductive film formed on the third conductive film.

3. The semiconductor device of claim 2, wherein
a material of the first conductive film is identical with a material of the third conductive film, and
a material of the second conductive film is identical with a material of the fourth conductive film.

4. The semiconductor device of claim 1, wherein
the insulating film is an oxide film containing Hf, Zr, La, Al, Lu, Gd, or Si, a nitride film containing Hf, Zr, La, Al, Lu, Gd, or Si, or an oxynitride film containing Hf, Zr, La, Al, Lu, Gd, or Si.

5. The semiconductor device of claim 1, wherein
the insulating film is an oxide film containing the silicon, a nitride film containing the silicon, or an oxynitride film containing the silicon.

6. The semiconductor device of claim 1, wherein
the insulating film is an oxide film containing the metal, a nitride film containing the metal, or an oxynitride film containing the metal.

7. The semiconductor device of claim 1, wherein
the first conductive film is a nitride film containing the metal, a carbide film containing the metal, or a silicon compound film containing the metal.

8. The semiconductor device of claim 1, wherein
the metal is at least one of Al, Fe, Cu, Ni, Co, Ti, Ta, Nb, W, Mo, V, Pt, and Au.

9. The semiconductor device of claim 1, wherein
the second conductive film is a polysilicon film, an amorphous silicon film, or a monocrystalline silicon film.

10. A semiconductor device comprising:
a resistive element; and
a MISFET,
wherein the resistive element includes
a first conductive film formed on a semiconductor substrate and containing a metal;
a second conductive film formed on the first conductive film and containing silicon; and
an insulating film formed between lower and upper parts of the second conductive film.

11. The semiconductor device of claim 10, wherein
the MISFET includes
a gate insulating film formed on the semiconductor substrate; and
a gate electrode including a third conductive film formed on the gate insulating film, and a fourth conductive film formed on the third conductive film.

12. The semiconductor device of claim 11, wherein
a material of the first conductive film is identical with a material of the third conductive film, and
a material of the second conductive film is identical with a material of the fourth conductive film.

13. The semiconductor device of claim 10, wherein
the insulating film is an oxide film containing the silicon, a nitride film containing the silicon, or an oxynitride film containing the silicon.

14. The semiconductor device of claim 10, wherein
the first conductive film is a nitride film containing the metal, a carbide film containing the metal, or a silicon compound film containing the metal.

15. The semiconductor device of claim 10, wherein
the metal is at least one of Al, Fe, Cu, Ni, Co, Ti, Ta, Nb, W, Mo, V, Pt, and Au.

16. The semiconductor device of claim 10, wherein
the second conductive film is a polysilicon film, an amorphous silicon film, or a monocrystalline silicon film.

17. A method for fabricating a semiconductor device including a resistive element formed on a resistive element region, and a MISFET formed on a MISFET region, the method comprising:
forming a first conductive film formation film containing a metal on a semiconductor substrate;
forming an insulating film formation film on the first conductive film formation film;
removing a portion of the insulating film formation film corresponding to the MISFET region;
after the removing, forming a second conductive film formation film which contains silicon and covers a remaining portion of the insulating film formation film and a portion of the first conductive film formation film corresponding to the MISFET region; and
after the forming the second conductive film formation film, sequentially patterning portions of the second conductive film formation film, the insulating film formation film, and the first conductive film formation film corresponding to the resistive element region, thereby forming the resistive element on the semiconductor substrate, where the resistive element includes a first conductive film made of the first conductive film formation film, an insulating film made of the insulating film formation film, and a second conductive film made of the second conductive film formation film.

18. The method of claim 17 further comprising:
before the forming the first conductive film formation film, forming a gate insulating film formation film on a portion of the semiconductor substrate corresponding to the MISFET region; and
after the forming the second conductive film formation film, sequentially patterning portions of the second conductive film formation film, the first conductive film formation film, and the gate insulating film formation film corresponding to the MISFET region, thereby sequentially forming a gate insulating film made of the gate insulating film formation film, and a gate electrode on the semiconductor substrate, where the gate electrode includes a third conductive film made of the first conductive film formation film and a fourth conductive film made of the second conductive film formation film,
wherein the sequentially patterning the portions corresponding to the resistive element region and the sequentially patterning the portions corresponding to the MISFET region are simultaneously performed.
